(19) United States
(12) Patent Application Publication
(10) Pub. No.: US 2024/0305534 A1
(43) Pub. Date: Sep. 12, 2024

(54) Scalable Mixed-Effect Modeling and Control

(71) Applicant: Google LLC, Mountain View, CA (US)

(72) Inventors: Ali Nasiri Amini, Redwood City, CA (US); Zheng Zhao, San Jose, CA (US); Di-Fa Chang, Cupertino, CA (US)

(21) Appl. No.: 18/009,487

(22) PCT Filed: Sep. 9, 2022
(86) PCT No.: PCT/US2022/043090

§ 371 Date: Dec. 9, 2022

(51) Int. Cl. H04L 41/14

(52) U.S. Cl. CPC H04L 41/145

(57) ABSTRACT

In an example aspect, the present disclosure provides for an example method including obtaining session data descriptive of one or more user sessions in the networked environment; initializing a mixed effects model configured to describe a first effect and a second effect on a distribution of the session data; optimizing a weighted objective over a plurality of subsets of the session data, the weighted objective comprising a weighting parameter configured to adjust, respectively for the plurality of subsets of the session data, a contribution of the second effect with respect to the first effect; and updating the mixed effects model based on the optimized weighted objective.

### FIELD

The present disclosure relates generally to techniques for modeling mixed effects in a system and optionally facilitating control of the system. In particular, the present disclosure relates to scalable techniques for mixed effects modeling and control.

### BACKGROUND

Real-world systems can demonstrate complex behavior. Actions and reactions can be interrelated, such that understanding and controlling aspects of interest in the systems can be difficult. Mixed effects models can be used to evaluate and isolate an effect of a parameter of interest among other interrelated features.

### SUMMARY

Aspects and advantages of embodiments of the present disclosure will be set forth in part in the following description, or can be learned from the description, or can be learned through practice of the embodiments.

In an example aspect, the present disclosure provides for an example method for selective distribution of content items. In some embodiments, the example method includes obtaining, by a computing system having one or more processors, session data descriptive of one or more client sessions in a networked environment, wherein a respective client session indicates a sequence of interaction events. In some embodiments of the example method, the sequence of interaction events can include an intermediate interaction with a content item rendered on a respective client device, the content item transmitted to the client device according to one or more distribution parameters, and a target interaction with a target networked resource associated with the content item. In some embodiments, the example method includes initializing, by the computing system, a mixed effects model configured to describe a first effect and a second effect on a distribution of the session data. In some embodiments, the example method includes optimizing, by the computing system, a weighted objective over a plurality of subsets of the session data, the weighted objective including a weighting parameter configured to adjust, respectively for the plurality of subsets of the session data, a contribution of the second effect with respect to the first effect. In some embodiments the example method includes updating, by the computing system, the mixed effects model based on the optimized weighted objective. In some embodiments the example method includes determining, by the computing system and based on the mixed effects model, an update to the distribution parameters, the update configured to decrease transmission of content items associated with a low probability of the target interaction.

In an example aspect, the present disclosure provides for an example method for modeling mixed effects in a networked environment. In some embodiments, the example method includes obtaining, by a computing system having one or more processors, session data descriptive of one or more user sessions in the networked environment. In some embodiments, the example method includes initializing, by the computing system, a mixed effects model configured to describe a first effect and a second effect on a distribution of the session data. In some embodiments, the example method includes optimizing, by the computing system, a weighted objective over a plurality of subsets of the session data, the weighted objective including a weighting parameter configured to adjust, respectively for the plurality of subsets of the session data, a contribution of the second effect with respect to the first effect. In some embodiments, the example method includes updating, by the computing system, the mixed effects model based on the optimized weighted objective.

In some embodiments of the example method(s), the second effect is associated with one or more levels of values in the session data, and wherein the weighted parameter is based on a frequency that a respective level associated with an input to the weighted objective appears in the session data.

In some embodiments of the example method(s), the weighted parameter is based on a size of a respective subset of the plurality of subsets.

In some embodiments of the example method(s), optimizing the weighted objective includes inverting, by the computing system, a data structure descriptive of at least a portion of a respective subset of the plurality of subsets.

In some embodiments of the example method(s), the mixed effects model disambiguates the first effect and the second effect.

In some embodiments of the example method(s), the first effect is associated with a causal relationship between an intermediate interaction with a content item rendered on a respective client device, the content item transmitted to the client device according to one or more distribution parameters, and a target interaction with a target networked resource associated with the content item.

In some embodiments of the example method(s), the weighted objective is optimized by stochastic gradient descent.

In some embodiments of the example method(s), the method includes estimating, by the computing system, a prior for a feature corresponding to the second effect; and estimating, by the computing system and based on the estimated prior, one or more weights for modeling the feature in the mixed effects model.

In some embodiments of the example method(s), the weighted objective is optimized over the plurality of subsets at least partially in parallel.

In some embodiments of the example method(s), the mixed effects model is updated by a first entity service provider system, wherein the first entity service provider system provides a modeling service to model behavior of a second entity content distribution system.

In some embodiments of the example method(s), a first entity service provider system implements the updated mixed effects model to control a distribution of content items on a second entity content distribution system.

In an example aspect, the present disclosure provides for an example one or more non-transitory computer-readable media storing instructions that are executable to cause one or more processors to perform operations, the operations including embodiments of the example method(s).

In an example aspect, the present disclosure provides for an example computing system having one or more processors and implementing the example one or more non-transitory computer-readable media storing instructions that are executable to cause one or more processors to perform operations, the operations including embodiments of the example method(s).

Other aspects of the present disclosure are directed to various systems, apparatuses, non-transitory computer-readable media, user interfaces, and electronic devices.

These and other features, aspects, and advantages of various embodiments of the present disclosure will become better understood with reference to the following description and appended claims. The accompanying drawings, which are incorporated in and constitute a part of this specification, illustrate example embodiments of the present disclosure and, together with the description, serve to explain the related principles.

### BRIEF DESCRIPTION OF THE DRAWINGS

Detailed discussion of embodiments directed to one of ordinary skill in the art is set forth in the specification, which makes reference to the appended figures, in which:

FIG. 1 depicts a block diagram of an example computing system for implementing mixed effect modeling according to example embodiments of the present disclosure;

FIG. 2 depicts a block diagram of an example computing system for implementing a control loop using mixed effect modeling according to example embodiments of the present disclosure:

FIG. 3A depicts a block diagram of an example computing system for implementing mixed effect modeling according to example embodiments of the present disclosure:

FIG. 3B depicts a block diagram of an example computing device for implementing mixed effect modeling according to example embodiments of the present disclosure:

FIG. 3C depicts a block diagram of an example computing device for implementing mixed effect modeling according to example embodiments of the present disclosure; and

FIG. 4 depicts a flow chart diagram of an example method for implementing mixed effect modeling according to example embodiments of the present disclosure.

FIG. 5 depicts an example application of mixed effect modeling according to example embodiments of the present disclosure.

FIG. 6 depicts a flow chart diagram of an example method for implementing mixed effect modeling according to example embodiments of the present disclosure.

FIG. 7 depicts a flow chart diagram of an example method for implementing mixed effect modeling according to example embodiments of the present disclosure.

Reference numerals that are repeated across plural figures are intended to identify the same features in various implementations.

### DETAILED DESCRIPTION

### Overview

Example embodiments according to the present disclosure provide for improved modeling and control of complex systems. For instance, example systems can facilitate content item distribution in a networked environment. For example, content items can be distributed for rendering on client devices to facilitate information dissemination and provide interactive interface elements for navigating within a networked environment using the client devices. Example mixed effect modeling techniques according to the present disclosure can more accurately determine likelihoods of successful deployment of content items by disambiguating among one or more random effects and a causal effect of transmitting the content item on achieving a target outcome. For instance, a target outcome can include interaction with the content item (e.g., utilization thereof). By more accurately identifying likelihoods of successful deployment and utilization, computational resources used to distribute and transmit content items can be more efficiently and effectively applied.

For instance, example embodiments can provide for scalable learning of mixture models. A mixture model can be descriptive of a probability distribution that includes multiple distributions of features. Some of the distributions can include random effects that do not relate to a feature of interest under investigation. For instance, a feature of interest under investigation may be related to successful deployment of an interactive content item that links to a networked resource. Session data can be obtained that describes a deployment of the content item and user interaction therewith. A target outcome can include successful access of the networked resource based on an interaction with the content item. Various features of the session data can provide signals that can be used to maximize a probability of the target outcome based on the modeling of the feature of interest (e.g., a fixed effect), but these features can be obfuscated in some situations by other features (e.g., random effects, such as differences in context that do not affect an underlying trend).

In some prior techniques, mixed effect models have been used to model the behavior of an effect of interest in view of various random effects. But generally, such techniques have been unable to efficiently scale. In particular, for example, such prior techniques have required full-batch optimization for fitting to an underlying dataset. This requirement can be cost-prohibited as datasets scale, rendering such techniques unavailable for many practical implementations in large networked environments.

Advantageously, example embodiments according to the present disclosure can provide for improved scalability of mixed effects models by facilitating the updating and learning of the model parameters using minibatch-based approaches. For instance, example embodiments advantageously provide for an iterative approach that adapts the model objectives to learn model parameters from minibatches while avoiding the skew that results from naively fitting a traditional mixed-effects model to minibatches of a dataset.

For example, in some embodiments, one or more parameters of a mixed effects model (e.g., linear mixed model, generalized linear mixed model, etc.) can be determined based on an optimization of an optimization objective. Of particular advantage, example embodiments according to the present disclosure can provide for adjusting an optimization objective based on one or more characteristics of a given minibatch. In this manner, for example, the optimization objective can be configured to accommodate learning parameters based on a sampling of a larger population of data instead of naively fitting the entire population directly.

In some embodiments, the optimization objective can include various component terms that respectively relate to fixed effects and random effects in the model. In some embodiments, the term(s) can be weighted to adapt the learning of the random effects to the context of minibatch-based learning. For instance, in some embodiments, one or more terms of an objective can be weighted based on a size of the minibatch, a size of the larger dataset, or a ratio thereof. In some embodiments, one or more terms of an objective can be weighted based on a frequency of a level of a corresponding random effect. In this manner, for example, the variance of random effects can advantageously be preserved and not artificially suppressed by the size of the minibatch unduly suggesting a small overall population size.

Example embodiments according to example aspects of the present disclosure can provide a number of technical effects and benefits. For example, mixed models can be used for modeling and control of many real-world systems in which a variable of interest is to be predicted and controlled among a number of random variables. However, real-world systems often include high degrees of complexity and expansive scope that give rise to large, high-dimensional datasets. Direct, full-batch solutions to mixed models—even if mathematically or theoretically feasible-generally involve matrix inversions that would be computationally infeasible in many practical applications. Advantageously, by facilitating the optimization of the models over minibatches of a larger dataset, example embodiments of the present disclosure can render feasible a class of system modeling and a scale of deployment previously unrealizable, especially in view of constrained computational resources (e.g., time, energy, compute cores, memory, etc.).

In some embodiments, example aspects of the present disclosure can provide for improved parallelization of the optimization or fitting of mixed effect models. For example, some prior techniques rely on full-batch processing. In contrast, the minibatch-based optimization enabled by example embodiments of the present disclosure is naturally amenable to parallelization due to the ability to process multiple minibatches in parallel. Accordingly, example embodiments of the present disclosure advantageously provide for improved parallelization of mixed effect modeling and control, increasing computational efficiency by utilization of multi-core, multi-worker processing hardware and systems.

In some embodiments, example aspects of the present disclosure can provide for improved accuracy and decreased latency by providing for computationally efficient techniques for modeling over larger datasets (e.g., for more accuracy, etc.) optionally at shorter update intervals (e.g., due to lower computational resource usage, etc.).

In some embodiments, aspects of the described technology can allow for more efficient allocation of computing resources by providing for a customization of a user interface with intelligently controlling content distribution system(s) based on predicted utilization associated with the distributed content item. The predicted utilization can provide a basis by which transmission of unused content items can be reduced. This can help reduce the computation processing and bandwidth usage by decreasing data transfer and decreasing the amount of data transmitted to a user device (e.g., indicative of one or more content items for user interface elements/input elements) based on whether that content item will actually be used. In this manner, for instance, example embodiments can provide for more efficient utilization of computational resources in resource-constrained environments.

In some embodiments, example aspects relate to improving a user's access to networked resources relevant to the user or the user's task(s) or otherwise facilitating an intent of the user when operating a computing system. For instance, by carefully selecting and distributing content items including input elements that provide a link or other access to a networked resource, and by providing those input elements to populate a user interface of a user computing device, the computing device can provide for a more efficient user-machine interface for accomplishing tasks and performing actions that may otherwise require a more complex or indirect sequence of inputs. For instance, instead of being required to access a first network resource providing an index of options, select an option for a vendor, scroll through various items from a vendor, and ultimately select a desired item, a user input element populated on the user interface can directly link to a network resource relating to a user's desired item. By learning to predict the utilization of input elements populated on a user interface based on the probability of relevance to achieving a user's task or goal, systems and methods according to the present disclosure can provide for more direct and efficient user interfaces for accomplishing particular tasks for which the user is using the computing device. In this manner, for instance, computational resources used to render multiple different interfaces to achieve a given task can be reduced (e.g., compute cycles, memory resources, electrical resources, etc.). Furthermore, the user-machine interface can be improved by providing for a more efficient and direct user interface flow for accomplishing a given task.

Additionally, or alternatively, example aspects of embodiments of the present disclosure can provide for adapting a user interface of a computing device to items that are actually relevant to a user's tasks or goals for using the computing device. For example, user activity may provide one or more signals that a particular input element would be relevant to accessing a resource of interest or performing a task at hand. However, systems and methods of the present disclosure can, in some embodiments, determine that rendering that particular input element would not be of sufficient incremental value to effectively improve the user interface (e.g., the user already has access to or otherwise is already navigating toward the resource of interest) based on a predicted utilization of that input element. Thus, systems and methods according to the present disclosure can, in some embodiments, update a model that de-prioritizes transmission of that input element to avoid wasting resources on rendering that input element.

With reference now to the Figures, example embodiments of the present disclosure will be discussed in further detail.

### Example Devices and Systems

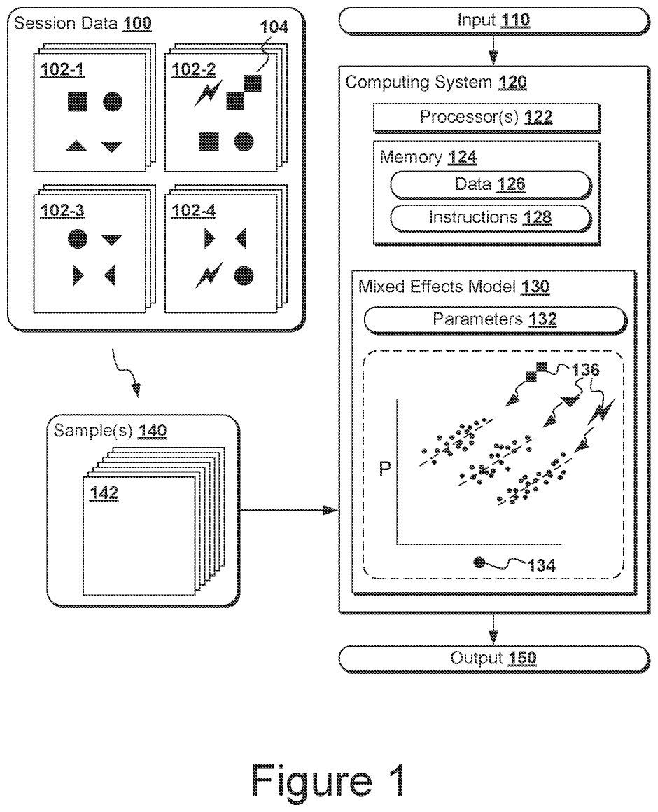

FIG. 1 depicts a block diagram of an example computing system for implementing mixed effect modeling and control according to example aspects of the present disclosure. Session data 100 descriptive of a subject system can be stored that describes a number of sessions of the system (e.g., sessions 102-1, 102-2, 102-3, 102-4, etc.) that are characterized by various features 104. To understand, characterize, or predict the behavior of the subject system, an input 110 (e.g., a query on the session data 100) can be provided to a computing system 120 (e.g., having processor(s) 122 and memory 124, storing data 126 and executable instructions 128) to implement a mixed effects model 130 characterized by parameters 132. The mixed effects model 130 can be configured, using the parameters 132, to model the effects of a feature of interest (e.g., feature 134) on the subject system while accounting for the variations induced by other features 104. The mixed effects model 130 can be configured with parameter values obtained by optimizing over samples 140 obtained from the session data 100, with the samples 140 containing minibatch(es) 142 of sessions. Based on the mixed effects model 130, an output 150 can be generated responsive to the input 110.

In some embodiments, the session data 100 can include data descriptive of activity in a networked environment. For instance, in some embodiments, the session data 100 can describe the behavior of a networked system of devices. For instance, in some embodiments, a subject system to be modeled can include a system for the distribution of content items from servers to various client devices.

The distributed content items can include various types of content. For instance, a content item can include interactive content or non-interactive content. For example, a content item can include audio content (e.g., recorded, synthesized, mixed, etc.), visual content (e.g., image(s), video, whether recorded or synthesized, etc.), and the like. In some embodiments, audio content can include verbal content, such as rendered speech content (e.g., radio, text-to-speech, neural-network generated speech, etc.).

In some embodiments, a content item can include one or more executable components. For instance, an executable component can include a hyperlink, address, or other executable instructions to retrieve additional content (e.g., a supplemental content item related to a primary content item). In some embodiments, an executable component can include a software component, such as an application or a portion thereof. For instance, a content item can include an interactive application experience, such as a game, service provider interface, content browsing interface, etc. for instance, a content item can include a browser component.

In some embodiments, a content item can be associated with a target resource. For instance, a content item distributed in a networked environment can include a pointer to (e.g., a link, etc.) a target networked resource (e.g., web page, audiovisual content, etc.) accessible by interaction with the content item. For instance, in some embodiments, a content item can include an interactive component (e.g., a user-selectable interface rendered in audio, graphical, or other media) such that an interaction with the content item facilitates access to the target networked resource. For instance, interaction with the content item on a client device can initiate navigation to or download of at least a portion of the target networked resource.

In some embodiments, an interaction that initiates access to a target resource can be a target interaction. For example, the target interaction can be a “click.” In some embodiments, one or more intermediate interactions may precede the target resource. For instance, an intermediate interaction can include rendering (e.g., by a client device, etc.) the content item.

In some embodiments, an interaction that consummates a transaction using a target resource can be a target interaction. For example, the target interaction can be a “conversion.” In some embodiments, an intermediate interaction can include engaging the content item (e.g., selecting, clicking, requesting, etc.) to navigate to or download at least a portion of the target resource.

In some embodiments, the session data 100 can include data descriptive of a plurality of sessions (e.g., session 102-1, session 102-2, session 102-3, session 102-4, etc.). Each session can be associated with the same or different client device(s). Each session can be associated with the same or different feature(s) 104. For instance, feature(s) 104 can include device characteristics (e.g., device identifier, device type, screen size, input type, device configurations, device location, etc.) or session characteristics (e.g., time, date, duration, activity type, inputs, outputs, interaction patterns, related activity, etc.), and the like.

An input 110 can be obtained related to the session data 100. For example, an input 110 can include a query over the session data 100. For example, a query over session data 100 can include a request for retrieving data descriptive of a relationship between interaction events and feature(s) of interest. Some features may be features of interest. Some features may be not currently of interest (e.g., in the context of a given query, etc.). In some embodiments, the input 110 is a query to determine features of interest. In some embodiments, input 110 includes instructions to generate an accounting for any interaction events recorded in the session data 100, including any associations between the features (e.g., features of interest, features not of interest) and the interaction events. In some embodiments, the input 110 can be a request for a prediction of interaction(s) based on one or more patterns in the session data 100.

The computing system 120 can process the input 110. The computing system 120 can be or include any type of computing device, such as, for example, a mobile computing device (e.g., smartphone or tablet), a personal computing device (e.g., laptop or desktop), a workstation, a server, a cluster, a gaming console or controller, a wearable computing device, an embedded computing device, or any other type of computing device, physical or virtual. computing system 120 can include one or more processors 122 and a memory 124. The one or more processors 122 can be any suitable processing device (e.g., a processor core, a microprocessor, an ASIC, an FPGA, a controller, a microcontroller, etc.) and can be one processor or a plurality of processors that are operatively connected. The memory 124 can include one or more non-transitory computer-readable storage media, such as RAM, ROM, EEPROM, EPROM, flash memory devices, magnetic disks, etc., and combinations thereof. The memory 124 can store data 126 and instructions 128 which can be executed by the processor 122 to cause the computing system 120 to perform operations, such as to implement a mixed effects model 130 as described herein.

Mixed effects model 130 can be or include a linear mixed effects model, a generalized linear mixed effects model, or the like, that can be parameterized by parameters 132. In general, mixed effects model 130 can model the effect(s) of a feature or variable of interest (e.g., feature 134) across the various possible context(s) presented by other features 136. For instance, as illustrated in FIG. 1, when the other features 136 are accounted for, it can be seen that the feature 134 corresponds to a positive slope as identified by the model 130 (e.g., whereas a naive regression across the datapoints would indicate a negative slope).

In some embodiments, the features (e.g., feature 134, other features 136, etc.) can be continuous. In some embodiments, the features (e.g., feature 134, other features 136, etc.) can be categorical. In some embodiments, the features (e.g., feature 134, other features 136, etc.) can include continuous and categorical features. In some embodiments, features (e.g., other features 136, etc.) can be treated as random effects.

In some embodiments, the response to be modeled can be continuous. In some embodiments, the response to be modeled can be discrete or categorical. For instance, in some embodiments, the response can be a predicted “click” or “conversion” associated with a content item.

In some embodiments, a mixed effects model 130 can include a number of supported prediction models. For the sake of illustration, various models will be discussed in detail below. It is to be understood, however, that the examples herein are non-limiting and are provided herein for the purposes of illustration and explanation only.

In some embodiments, the response to be modeled can be obtained using a Poisson-based model. For example, a click can be modeled as a feature of interest 134 (e.g., fixed effect) while other session features 136 can include features of a content item URL, content item identifier, etc. that can be modeled as random effects. For instance, the response can be modeled as Poisson(click, (wᵤᵣₗ+w_{id}+bias)·Normal(wᵤᵣₗ; σᵤᵣₗ)·Normal(w_{id}; σ_{id}).

In some embodiments, a joint likelihood function can be defined for a model 130. For instance, let n be the number of training examples, for example (yᵢ, xᵢ), i˜[1, . . . , n]. Let m be the number of random effects, such as, for example, each training example being a vector of m values: x_{i,j}, j˜[1, . . . , m]. Given a random effect Fⱼ which is a categorical feature, let it have Kⱼ unique values, such as, for example xᵢ, j∈[fⱼ, 1, . . . , fⱼ, Kⱼ]. Let w_{j,k} be the weight of the k-th value of feature Fⱼ. Let σⱼ be the prior of feature Fⱼ. Let cᵢ be the offset of the i-th training example. And let b be the bias term of the model.

A Poisson-Lognormal joint likelihood can be expressed as in Equation 1.

$$\text{?} ( \text{?} \text{?} X \vert W \text{?} ) \text{?} ( W \vert \sum ) = ( \prod \text{?} ( \text{?} \text{?} exp ( \sum \text{?} \text{?} \text{?} ) ) ) \prod \text{?} \text{?} ( \text{?} \text{?} \text{?} ) \qquad ( 1 )$$

$$\text{?} \text{indicates text missing or illegible when filed}$$

A Bernoulli-logitnormal joint likelihood can be expressed as in Equation 2.

$$\text{?} ( \text{?} \text{?} X \vert W \text{?} ) \text{?} ( W \vert \sum ) = \{ \prod \text{?} [ \text{?} ( \text{?} \text{?} ( \sum \text{?} \text{?} \text{?} ) ) ] \text{?} \} \text{?} ( \text{?} \text{?} \text{?} ) \qquad ( 2 )$$

$$\text{?} \text{indicates text missing or illegible when filed}$$

A Gaussian-Gaussian joint likelihood can be expressed as in Equation 3.

$$\text{?} \text{?} \text{?} \text{?} X \vert W \text{?} \text{?} ) \text{?} ( W \vert \sum ) = ( \prod \text{?} ( \text{?} ( \sum \text{?} \text{?} \text{?} ) \text{?} ( \text{?} \text{?} \text{?} ( \text{?} \text{?} ) ) \prod \text{?} \text{?} ( \text{?} \text{?} \text{?} ) \qquad ( 3 )$$

$$\text{?} \text{indicates text missing or illegible when filed}$$

In some embodiments, features can be categorized into groups. For instance, in one example, consider four groups F_{RR}, F_{RC}, F_{FR}, F_{FC}, which denote the set of random effects with real feature values, the set of random effects with categorical feature values, the set of fixed effects with real feature values, and the set of fixed effects with categorical feature values, respectively. The likelihood mean can be rewritten as shown in Equation 4,

$$\sum \text{?} \text{?} \text{?} \text{?} \sum \text{?} \text{?} \text{?} \sum \text{?} \text{?} \text{?} \qquad ( 4 )$$

$$\text{?} \text{indicates text missing or illegible when filed}$$

and the priors can be rewritten as shown in Equation 5.

$$\prod \text{?} \text{?} \text{?} \text{?} \text{?} \prod \text{?} \text{?} \text{?} \text{?} \prod \text{?} \text{?} \text{?} \text{?} \text{?} \qquad ( 5 )$$

$$\text{?} \text{indicates text missing or illegible when filed}$$

It can also be possible to apply regularization on fixed effects. Adding regularization to fixed effects can provide a way to control the scale or variance of weights, which can improve model performance in machine learning applications. In some embodiments, these fixed effects can be considered as random effects with fixed prior values.

By constructing design matrices for fixed and random effects using one-hot encoding, one can rewrite the linear part of the distributions specified in Equations 1-3 as in Equation 5.

$$\sum \text{?} + \sum \text{?} \text{?} \text{?} \text{?} \text{?} \text{?} \text{?} \text{?} β \text{?} \text{?} \text{?} \text{?} \qquad ( 6 )$$

$$\text{?} \text{indicates text missing or illegible when filed}$$

In the above equation, qᵢ is a row vector and corresponds to the part of the i-th training example that contains all fixed effects and the bias term. For categorical fixed effects, one-hot encoding can be used. For the bias term, its corresponding element in qᵢ is 1.

Therefore, the dimension of weight vector β can be expressed as in Equation 7.

$$\text{?} \text{?} \text{?} \text{?} \sum \text{?} \text{?} \text{?} \text{?} \qquad ( 7 )$$

$$\text{?} \text{indicates text missing or illegible when filed}$$

Let zᵢ be a row vector that corresponds to the part of the i-th training example that contains all random effects. For categorical random effects, one-hot encoding can be used, and the dimension of weight vector γ can be expressed as in Equation 8.

$$\text{?} \text{?} \text{?} \text{?} \sum \text{?} \text{?} \qquad ( 8 )$$

$$\text{?} \text{indicates text missing or illegible when filed}$$

Given n examples, this can be written in matrix format as in Equation 9.

$$\text{?} β \text{?} Z \text{?} \text{?} Q = ( \begin{matrix}\text{?} \\ \text{?} \\ \text{?}\end{matrix} ) \text{?} \qquad ( 9 )$$

$$Z = ( \begin{matrix}\text{?} \\ \text{?} \\ \text{?}\end{matrix} ) \text{?}$$

$$\text{?} \text{indicates text missing or illegible when filed}$$

In some embodiments, a linear mixed effect model can be written as in Equation 10.

$$y \text{?} \text{?} β \text{?} Z \text{?} \text{?} \text{?} \qquad ( 10 )$$

$$\text{?} \text{?} \text{?} \text{?} \text{?}$$

$$\text{?} \text{?} \text{?} ( \text{?} , R )$$

$$\text{?} \text{indicates text missing or illegible when filed}$$

In the equation, G and R are the covariance matrices of γ and ε. For the problem specified in Equation (3), its corresponding linear mixed model has a diagonal covariance matrix that can be specified as in Equation 11.

$$G = [ \begin{matrix}{σ}_{\text{?}}^{2} & & \\ & ⋱ & \\ & & {σ}_{m}^{2}\end{matrix} ] , {σ}_{j}^{2} = [ \begin{matrix}{σ}_{j}^{2} & & \\ & ⋱ & \\ & & {σ}_{j}^{2}\end{matrix} ] ∈ {ℝ}^{{K}_{j} \times {K}_{j}} , R = d \cdot [ \begin{matrix}{c}_{\text{?}} & & \\ & ⋱ & \\ & & {c}_{N}\end{matrix} ] \qquad ( 11 )$$

$$\text{?} \text{indicates text missing or illegible when filed}$$

As y is a linear combination of normal distributions, it also follows a normal distribution, and the covariance matrix of this normal distribution has the form of Equation 12.

$$V = {ZGZ}^{\text{?}} + R \qquad ( 12 )$$

$$\text{?} \text{indicates text missing or illegible when filed}$$

This leads to a marginal model of y.

$$y = Q β + {ε}^{*} , {ε}^{*} \sim Normal ( 0 , V ) \qquad ( 13 )$$

The MLE or weighted LSE of β can be expressed as in Equation 14.

$$\tilde{β} = {( {Q}^{\text{?}} {V}^{- 1} Q )}^{- 1} {Q}^{\text{?}} {V}^{- 1} y \qquad ( 14 )$$

$$\text{?} \text{indicates text missing or illegible when filed}$$

As y˜Normal(Qβ, V) and γ˜Normal (0, G), it can be determined that Cov (y, γ)=ZG, when Cov (Qβ, γ)=0 and Cov (ε, γ)=0. One can derive the conditional distribution of γ given y from the joint distribution of (y,γ), which leads to a normal distribution and its mean can be the best linear unbiased predictor of γ (BLUP).

$$E ( γ \vert y ) = {GZ}^{\text{?}} {V}^{- 1} ( y - Q β ) \qquad ( 15 )$$

$$\text{?} \text{indicates text missing or illegible when filed}$$

By plugging in \tilde{β}, one can obtain the empirical BLUP of γ, which can be expressed as in Equation 16.

$$\tilde{γ} = {GZ}^{\text{?}} {V}^{- 1} ( y - Q \tilde{β} ) \qquad ( 16 )$$

$$\text{?} \text{indicates text missing or illegible when filed}$$

Equations (10) and (12) can present a solution of the mixed model equation. They can obtained by maximizing P(y|γ)P(γ) via solving the Henderson equation expressed in Equation 17.

$$( \begin{matrix}{Q}^{\text{?}} {R}^{- 1} Q & {Q}^{\text{?}} {R}^{- 1} Z \\ {Z}^{\text{?}} {R}^{- 1} Q & {Z}^{\text{?}} {R}^{- 1} Z + {G}^{- 1}\end{matrix} ) ( \begin{matrix}\tilde{β} \\ \tilde{γ}\end{matrix} ) = ( \begin{matrix}{Q}^{\text{?}} {R}^{- 1} y \\ {Z}^{\text{?}} {R}^{- 1} y\end{matrix} ) \qquad ( 17 )$$

$$\text{?} \text{indicates text missing or illegible when filed}$$

To compute β and γ, one would need to know V, G, and R. According to Equation (11), these matrices are parameterized by (σ₁², . . . , σₘ²) and d. These parameters can be estimated by maximizing the likelihood y, which can be obtained by further marginalizing out β from the marginal model of y defined in Equation 13. This leads to a restricted maximum likelihood estimation (REML) of (σ₁², . . . , σₘ²) and d. More specifically, the REML estimation of the log-likelihood can be defined as in Equation 18,

$$R E M L : {l}_{R} ( G , R ) = - \frac{1}{2} log \vert V \vert - \frac{1}{2} log \vert {Q}^{\text{?}} {V}^{- 1} Q \vert - \frac{1}{2} {r}^{\text{?}} {V}^{- 1} r - const \qquad ( 18 )$$

$$\text{?} \text{indicates text missing or illegible when filed}$$

where

$$r = y - Q β \qquad ( 19 )$$

Similarly, one can also derive the maximum likelihood estimation of the log-likelihood, which can be expressed as in Equation 20.

$$M L : {l}_{R} ( G , R ) = - \frac{1}{2} log \vert V \vert - \frac{1}{2} {r}^{\text{?}} {V}^{- 1} r - const \qquad ( 20 )$$

$$\text{?} \text{indicates text missing or illegible when filed}$$

To help stochastic gradient descent converge to a good local optimal solution when solving a non-convex problem, it can be helpful to initialize model parameters with a starting point that is in the vicinity of a good local optimal solution. This can be achieved by solving linear mixed models with infinite prior values, which results in a linear regression model. In this case, the problem is convex and has a unique optimal solution. Based on the solution of \tilde{β}, and \tilde{γ}, returned by the linear regression model, σⱼ can be initialized by computing the variance of its corresponding elements in \tilde{γ}. Algorithm (1) contains the pseudo code for fitting a linear mixed model with initialization via solving a linear regression model.

Algorithm 1 Fitting A Linear Mixed Model

| | |
|---|---|
| 1: | procedure LMM(X_{B}, Z, y); |
| 2: | Estimate \tilde{β}′ and \tilde{γ}′ via fitting a linear |
| | mixed model using infinite prior values; |
| 3: | Calculate \tilde{σ}ⱼ′ as the variance of its corresponding |
| | elements in \tilde{γ}, for j = 1,...,m; |
| 4: | Initialize \tilde{β}, \tilde{γ}, |
| | and \tilde{σ} as \tilde{β}′, |
| | \tilde{γ}′ and \tilde{σ}′; |
| 5: | |
| 6: | Estimate \tilde{β}, \tilde{G} |
| | and \tilde{R} via SGD by minimizing |
| | log \|V\| + log \|Q^{T}V⁻¹Q\| + (y − Qβ)^{T}V⁻¹ (y − Qβ); |
| 7: | Given (σₗ²,...,σₘ²), \tilde{β} and d, compute \tilde{γ} via SGD. |
| 8: | |
| 9: | return \tilde{β}, \tilde{γ}, |
| | \tilde{G} and \tilde{R}; |
| 10: | end procedure |

In some embodiments, a generalized linear mixed effect model can be solved by pseudo-likelihood estimation based on linearization, which boils down to fitting a series of linear mixed models with different specifications of pseudo-response and residual variance. Let g⁻¹(η) be the inverse link function. For Poisson-Lognormal, g⁻¹(η) is the exp function, and for Bernoulli-Lognormal, g⁻¹(n) is the expit function. The idea of linearization is based on approximating E (Y|γ) with first order Taylor expansion,

$$E ( Y \vert γ ) = {g}^{- 1} ( Q β + Z γ ) = {g}^{- 1} ( η ) = μ , where γ \sim N ( 0 , G ) , Var ( Y \vert γ ) = {A}^{\frac{1}{2}} {RA}^{\frac{1}{2}} \qquad ( 21 )$$

where A is a diagonal matrix and contains the variance functions of the model. More specifically, its diagonal elements capture the variance of response when response mean is given. And the matrix R is a variance matrix capturing the covariance structure of residual effects. For models specified in Equations (1) and (2), R is an identity matrix, R=I and Var(Y|γ)=A. Given an estimation of \tilde{β}, and \tilde{γ}, the first order approximation of E (Y|γ) around \tilde{β}, and \tilde{γ}, can be written as in Equation 22.

$${g}^{- 1} ( η ) \approx {g}^{- 1} ( \tilde{η} ) + \tilde{Δ} Q ( β - \tilde{β} ) + \tilde{Δ} Z ( γ - \tilde{γ} ) , where \tilde{η} = Q \tilde{β} + Z \tilde{γ} , \tilde{Δ} = {( \frac{\partial {g}^{- 1} ( η )}{\partial η} )}_{\tilde{β} , \tilde{γ}} \qquad ( 22 )$$

Equation 22 can be rewritten as in Equation 19.

$${\tilde{Δ}}^{- 1} ( {g}^{- 1} ( η ) - {g}^{- 1} ( \tilde{η} ) ) + Q \tilde{β} + Z \tilde{γ} \approx Q β + Z γ \\ ⇒ {\tilde{Δ}}^{- 1} ( y - {g}^{- 1} ( \tilde{η} ) ) + Q \tilde{β} + Z \tilde{γ} \approx Q β + Z γ \qquad ( 22 )$$

The pseudo-response can be defined as in Equation 23.

$$p = {\tilde{Δ}}^{- 1} ( y - {g}^{- 1} ( \tilde{η} ) ) + Q \tilde{β} + Z \tilde{γ} \qquad ( 23 )$$

This provides Equation 24.

$$p = Q β + Z γ + ε , where p = {\tilde{Δ}}^{- 1} ( y - {g}^{- 1} ( \tilde{η} ) ) + Q \tilde{β} + \vert Z \tilde{γ} \qquad ( 24 )$$

Equation 24 defines a linear mixed model with pseudo-response p, fixed effects β, random effects γ. Given the definition of p, Var (ε)=Var (p|γ). And this variance term can be formulated as in Equation 25.

$$Var ( p \vert γ ) = {\tilde{Δ}}^{- 1} {\tilde{A}}^{\frac{1}{2}} R {\tilde{A}}^{\frac{1}{2}} {\tilde{Δ}}^{- 1} = {\tilde{Δ}}^{- 1} \tilde{A} {\tilde{Δ}}^{- 1} \qquad ( 25 )$$

And the V matrix defined by this linear mixed model can be expressed as in Equation 26.

$$V = {ZGZ}^{⊤} + {\tilde{Δ}}^{- 1} \tilde{A} {\tilde{Δ}}^{- 1} \qquad ( 26 )$$

The REML and ML estimation for the log-likelihood of this problem can be expressed as follows.

$$REML : {l}_{R} ( G , R ) = - \frac{1}{2} log \vert V \vert - \frac{1}{2} log \vert {Q}^{⊤} {V}^{- 1} Q \vert - \frac{1}{2} {r}^{⊤} {V}^{- 1} r - const \qquad ( 27 )$$

$$ML : {l}_{R} ( G , R ) = - \frac{1}{2} log \vert V \vert - \frac{1}{2} {r}^{⊤} {V}^{- 1} r - const \qquad ( 28 )$$

$$r = p - Q \tilde{β} \qquad ( 29 )$$

Solving the problem specified in Equation (24) leads to an new estimation of \tilde{β}, \tilde{γ}, and \tilde{σ}. One can repeat this process, until the estimation of \tilde{β}, \tilde{γ}, and \tilde{σ} becomes stable. Table 1 shows examples of how A and Δ can be computed for different distributions.

TABLE 1

| | μ = g⁻¹ (η) | A [symbol] _{,} [symbol] | Δ [symbol] _{,} [symbol] | (Δ⁻¹A Δ⁻¹) [symbol] _{,} [symbol] |
|---|---|---|---|---|
| Poisson | μ [symbol] = exp (η [symbol] ) | μ [symbol] | μ [symbol] | μ [symbol] ⁻¹ |
| Bernoulli | μ [symbol] = exp [symbol] (η [symbol] ) | μ [symbol] (1 − μ [symbol] ) | μ [symbol] (1 − μ [symbol] ) | (μ [symbol] (1 − |
| | | | | μ [symbol] ))⁻¹ |

[symbol]

indicates data missing or illegible when filed

In some embodiments (e.g., linear mixed effect models, generalized linear mixed effect models, etc.), γ can be computed via minimizing the negative log joint likelihood, which are convex functions when σ is given. In this case, for example an SGD style optimizer can be used to solve the problem.

In some examples, the following objective functions can be used for each minibatch when different distributions are used. For the Poisson-Lognormal distribution:

$${arg min}_{γ} {\sum }_{i}^{\text{?}} log Pois ( {y}_{i} ; {c}_{i} \cdot exp ( {q}_{i} β + {z}_{i} γ ) ) + {\sum }_{{jk}_{j}} log Normal ( {w}_{j} {k}_{j} : 0 , {σ}_{j}^{2} ) , j ∈ {𝔽}_{R} , {k}_{j} ∈ \text{?} \qquad ( 30 )$$

$$\text{?} \text{indicates text missing or illegible when filed}$$

For the Bernoulli-Logitnormal distribution:

$${arg min}_{γ} {\sum }_{i}^{\text{?}} {c}_{i} log Bernoulli ( {y}_{i} ; exp \text{?} ( {q}_{i} β + {z}_{i} γ ) ) + {\sum }_{{jk}_{j}} log Normal ( {w}_{j} {k}_{j} : 0 , {σ}_{j}^{2} ) , j ∈ {𝔽}_{R} , {k}_{j} ∈ \text{?} \qquad ( 31 )$$

$$\text{?} \text{indicates text missing or illegible when filed}$$

In Equations 30 and 31,

$$j ∈ {𝔽}_{R} , {k}_{j} ∈ \text{?} \qquad ( 32 )$$

$$\text{?} \text{indicates text missing or illegible when filed}$$

denotes the set of weights, which correspond to the levels of random effects that appear in the current minibatch.

Advantageously, to avoid introducing error into the analysis from optimizing over the sampled minibatch, a weighting parameter can be applied to reweight the objective.

In some embodiments, a weighting parameter can be determined based on a characteristic of the minibatch, the total population, or both. For instance, in some embodiments, a weighting parameter can be based on a ratio of the minibatch size n_{B} to the population size n. For the Poisson-Lognormal distribution:

$${arg min}_{γ} {\sum }_{i}^{\text{?}} log Pois ( {y}_{i} ; {c}_{i} \cdot exp ( {q}_{i} β + {z}_{i} γ ) ) + \frac{{n}_{B}}{n} {\sum }_{{jk}_{j}} log Normal ( {w}_{j} {k}_{j} : 0 , {σ}_{j}^{2} ) , j ∈ {𝔽}_{R} , {k}_{j} ∈ \text{?} \qquad ( 33 )$$

$$\text{?} \text{indicates text missing or illegible when filed}$$

For the Bernoulli-Logitnormal distribution:

$${arg min}_{γ} {\sum }_{i}^{\text{?}} {c}_{i} log Bernoulli ( {y}_{i} ; exp \text{?} ( {q}_{i} β + {z}_{i} γ ) ) + \frac{{n}_{B}}{n} {\sum }_{{jk}_{j}} log Normal ( {w}_{j} {k}_{j} : 0 , {σ}_{j}^{2} ) , j ∈ {𝔽}_{R} , {k}_{j} ∈ \text{?} \qquad ( 34 )$$

$$\text{?} \text{indicates text missing or illegible when filed}$$

In some embodiments, the objective can be pooled for the n_{B} training examples in the minibatch. For the Poisson-Lognormal distribution:

$${arg min}_{γ} {\sum }_{i}^{\text{?}} ( log Pois ( {y}_{i} ; {c}_{i} \cdot exp ( {q}_{i} β + {z}_{i} γ ) ) + \frac{1}{n} {\sum }_{j ∈ {𝔽}_{R}} log Normal ( {w}_{{jx}_{i , j}} : 0 , {σ}_{j}^{2} ) ) \qquad ( 35 )$$

$$\text{?} \text{indicates text missing or illegible when filed}$$

For the Bernoulli-Logitnormal distribution:

$${arg min}_{γ} {\sum }_{i}^{\text{?}} ( {c}_{i} log Bernoulli ( {y}_{i} ; exp \text{?} ( {q}_{i} β + {z}_{i} γ ) ) + \frac{1}{n} {\sum }_{j ∈ {𝔽}_{R}} log Normal ( {w}_{j , {x}_{i , j}} ; 0 , {σ}_{j}^{2} ) ) \qquad ( 36 )$$

$$\text{?} \text{indicates text missing or illegible when filed}$$

In the above equations, w_{j,xi,j}, j∈F_{R} denotes the weights of random effect levels that appear in the i-th training example.

In some embodiments, the prior loss of each random effect level can be reweighted by its frequency, such as, for example, how many times that level appears in the training data. For the Poisson-Lognormal distribution:

$${arg min}_{γ} {\sum }_{i}^{\text{?}} ( log Pois ( {y}_{i} ; {c}_{i} \cdot exp ( {q}_{i} β + {z}_{i} γ ) ) + {\sum }_{j ∈ {𝔽}_{R}} \frac{1}{{f}_{j , xi , j}} log Normal ( {w}_{j , {x}_{i , j}} ; 0 , {σ}_{j}^{2} ) ) \qquad ( 37 )$$

$$\text{?} \text{indicates text missing or illegible when filed}$$

For the Bernoulli-Logitnormal distribution:

$${arg min}_{γ} {\sum }_{i}^{\text{?}} ( {c}_{i} log Bernoulli ( {y}_{i} ; exp \text{?} ( {q}_{i} β + {z}_{i} γ ) ) + {\sum }_{j ∈ {𝔽}_{R}} \frac{1}{{f}_{j , xi , j}} log Normal ( {w}_{j , {x}_{i , j}} ; 0 , {σ}_{j}^{2} ) ) \qquad ( 38 )$$

$$\text{?} \text{indicates text missing or illegible when filed}$$

In the above equations, f_{j,xi,j} is the frequency of the x_{i,j} level of random effect j. The frequency information of random effect levels can be obtained in a preprocessing step.

Advantageously, optimizing over an epoch of training data using one of the weighted objectives above can recover the original objectives from Equations (1) and (2).

In some implementations, a Henderson equation for a generalized linear mixed effects model can have the form shown in Equation 39.

$$\begin{matrix}[ \begin{matrix}{Q}^{⊤} {S}^{- 1} Q & {Q}^{⊤} {S}^{- 1} Z \\ {Z}^{⊤} {S}^{- 1} Q & {Z}^{⊤} {S}^{- 1} Z + {G}^{- 1}\end{matrix} ] [ \begin{matrix}β \\ γ\end{matrix} ] = [ \begin{matrix}{Q}^{⊤} {S}^{- 1} p \\ {Z}^{⊤} {S}^{- 1} p\end{matrix} ] , & S = Var ( p \vert γ ) =\end{matrix} {\tilde{Δ}}^{- 1} {\tilde{A}}^{\frac{1}{2}} R {\tilde{A}}^{\frac{1}{2}} {\tilde{Δ}}^{- 1} \qquad ( 39 )$$

One can estimate γ by solving the Henderson equation, which leads to the following objective of Equation 40.

$$\begin{matrix}{arg min}_{γ} {‖ {Q}^{⊤} {S}^{- 1} ( η - p ) ‖}_{2}^{2} + {‖ {Z}^{⊤} {S}^{- 1} ( η - p ) + {G}^{- 1} γ ‖}_{2}^{2} , & η = Q β + Z γ\end{matrix} \qquad ( 40 )$$

In the equation, G⁻¹γ serves as a regularization from the priors. Advantageously, to avoid introducing error into the analysis from optimizing over the sampled minibatch, a weighting parameter can be applied to reweight the objective. For example, the regularization term can be weighted, as in Equation 41.

$$\begin{matrix}{arg min}_{γ} {‖ {Q}^{⊤} {S}^{- 1} ( η - p ) ‖}_{2}^{2} + {‖ {Z}^{⊤} {S}^{- 1} ( η - p ) + \frac{{n}_{B}}{n} {G}^{- 1} γ ‖}_{2}^{2} , & η = Q β + Z γ\end{matrix} \qquad ( 41 )$$

In this example objective function, S and G are all diagonal. By constructing Z and γ properly, the objective function can be efficiently implemented in computational systems.

For fitting a generalized linear mixed model, model parameters can be initialized with a starting point that is in the vicinity of a good local optimal solution. This can be achieved by solving generalized linear mixed models with a given initial prior value. As an example, one can use log(var(Y)) as an initial prior value for all features. This can lead to a generalized linear model with regularization. Another example is that one can also use +∞ as the prior value. In this case, a generalized linear model becomes a generalized linear model without any regularization.

The resulting problem can be convex and provide a unique optimal solution. Based on the solution of \tilde{β}, \tilde{γ} returned, σⱼ can be initialized by computing the variance of its corresponding elements in \tilde{γ}. Below is the pseudo-code for fitting a generalized linear mixed model (GLMM) based on the idea of linearization. In some embodiments, the computation of V is simplified when A=Δ.

Algorithm 2 Fitting A Generalized Linear Mixed Model

| | |
|---|---|
| 1: | procedure GLMM(X_{B}, Z, y, g(x)); |
| 2: | Estimate β^{[0]} and γ^{[0]} via fitting a generalized linear model with(out) regularization; |
| 3: | Calculate σⱼ^{[0]} as the variance of its corresponding elements in γ^{[0]}, for j = 1,...,m; |
| 4: | for (i = 1,...,T do |
| 5: | Initialize β^{[} [symbol] ^{]}, γ^{[} [symbol] ^{]}, and σ^{[} [symbol] ^{]} as β^{[} [symbol] ^{-1]}, γ^{[} [symbol] ^{-1]} and σ^{[} [symbol] ^{-1]}; |
| 6: | Construct p and V using β^{[} [symbol] ^{-1]} and γ^{[} [symbol] ^{-1]}; |
| | η^{[} [symbol] ^{-1]} = Xβ^{[} [symbol] ^{-1]} + Zγ^{[} [symbol] ^{-1]}, |
| | p = (Δ^{[} [symbol] ^{-1]})⁻¹ (y − g⁻¹ (η^{[} [symbol] ^{-1]})) + η^{[} [symbol] ^{-1]}, |
| | V = ZGZ^{T} + (Δ^{[} [symbol] ^{-1]})⁻¹ ; |
| 7: | Update β^{[} [symbol] ^{]} and σ^{[} [symbol] ^{]} via SGD by minimizing |
| | ML: log \|V\| + (p − Qβ)^{T} (V)⁻¹ (p − Qβ); |
| | or |
| | REML: log \|V\| + log \|Q^{T}V⁻¹Q\| + (p − Qβ)^{T} (V)⁻¹ (p − Qβ); |
| 8: | Update γ^{[} [symbol] ^{]}, given β^{[} [symbol] ^{]} and σ^{[} [symbol] ^{]}; |
| 9: | end for |
| 10: | return β^{[T]}, γ^{[T]}, σ^{[T]}; |
| 11: | end procedure |

[symbol]

indicates data missing or illegible when filed

In some embodiments, the output 150 includes one or more predictors of a target interaction. For instance, the output 150 can include a predicted probability associated with a target interaction.

In some embodiments, the output 150 includes one or more instructions generated based on one or more predictors of a target interaction. For instance, the output 150 can include one or more updates to one or more distribution processes (e.g., distribution models or distribution systems, etc.) determined based on the predictors to maximize a probability of a target interaction.

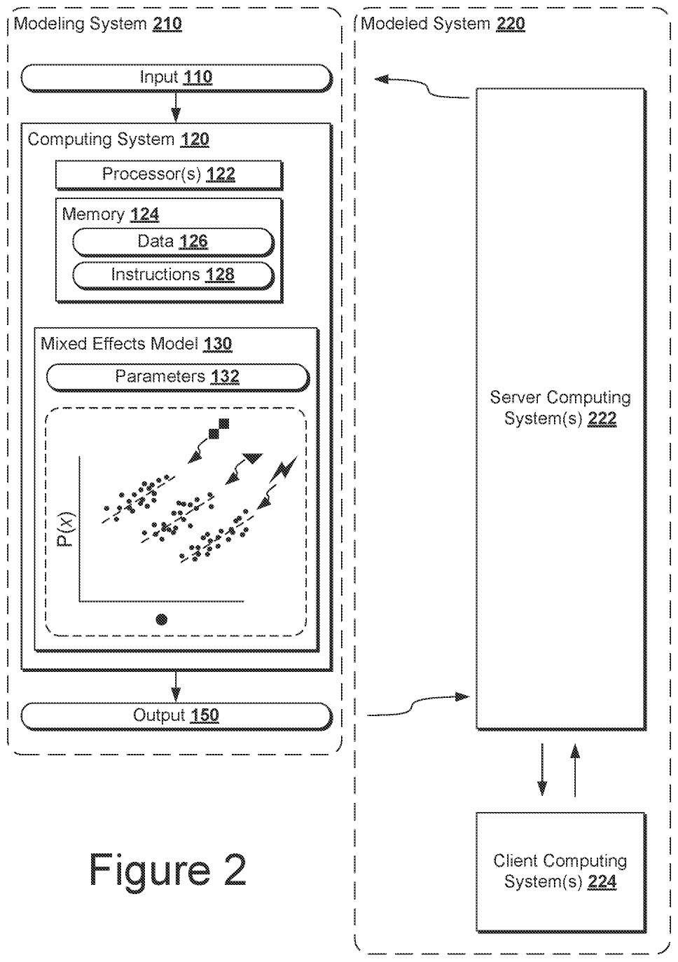

For example, FIG. 2 depicts a block diagram of an interplay between a modeling system 210 and a modeled system 220. The modeling system 210 can include the computing system 120. The modeling system 210 can receive data descriptive of activity on the modeled system 220 (e.g., session data 100 descriptive of sessions between server computing system(s) 222 and client computing system(s) 224, etc.), and an input 110 can be associated with a request for an update to the modeled system 220 (e.g., to optimize one or more parameters of server computing system(s) 222, etc.). The output 150 can include one or more updates or other instructions for adjusting the modeled system 220 in response to the input 110.

The modeled system 220 can be implemented on one or more computing systems, which may be the same as or different than the computing system 120. For instance, the modeled system 222 can be implemented, controlled, or managed by a first party, and the modeling system 210 can be implemented, controlled, or managed by a third party. For instance, the third party could provide the modeling and updates for the modeled system 220 as a service.

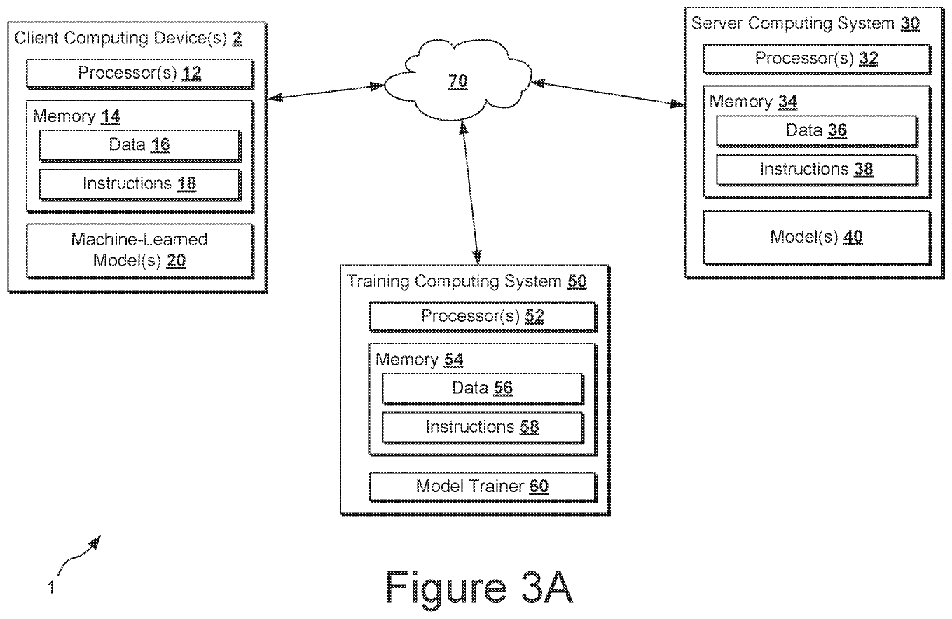

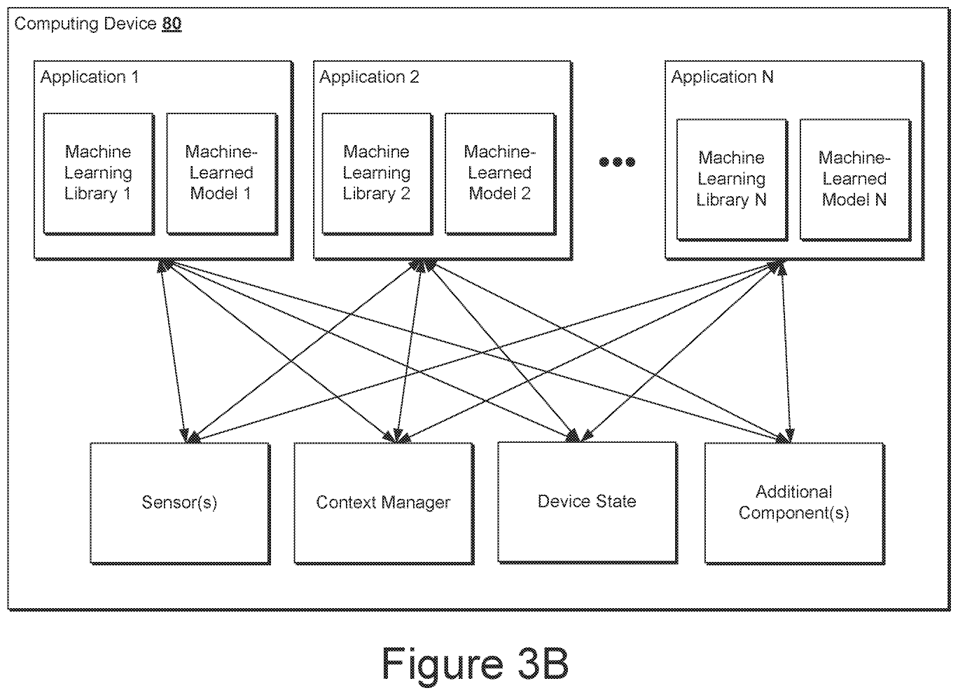

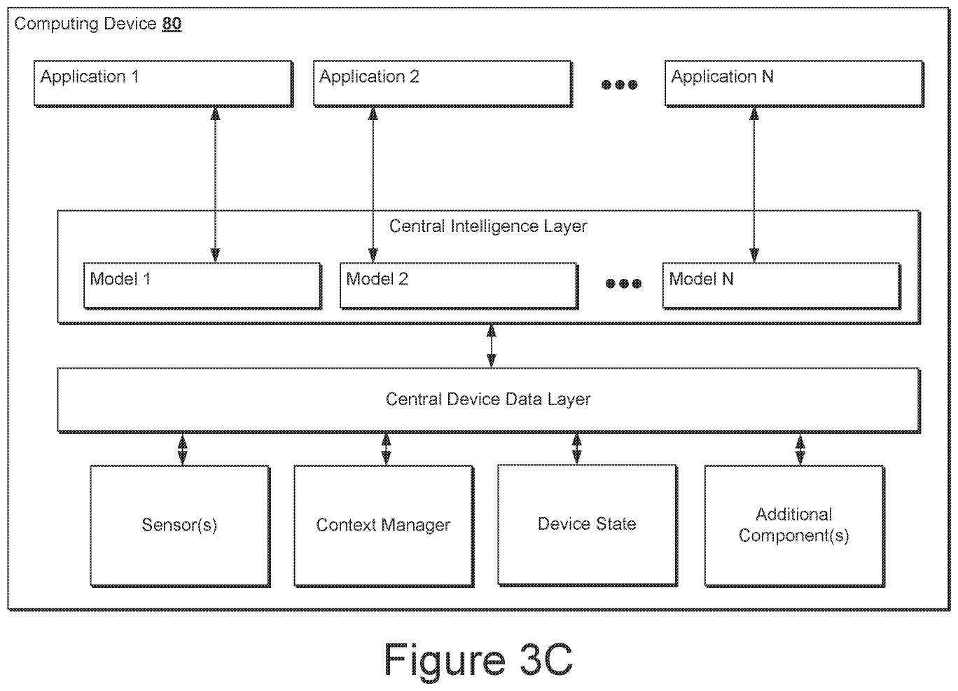

FIG. 3A depicts a block diagram of an example computing system 1 that can perform according to example embodiments of the present disclosure. The system 1 includes a client computing device 2, a server computing system 30, and a training computing system 50 that are communicatively coupled over a network 70.

The client computing device 2 can be any type of computing device, such as, for example, a mobile computing device (e.g., smartphone or tablet), a personal computing device (e.g., laptop or desktop), a workstation, a cluster, a gaming console or controller, a wearable computing device, an embedded computing device, or any other type of computing device. In some embodiments, the computing device 2 can be a client computing device. The computing device 2 can include one or more processors 12 and a memory 14. The one or more processors 12 can be any suitable processing device (e.g., a processor core, a microprocessor, an ASIC, an FPGA, a controller, a microcontroller, etc.) and can be one processor or a plurality of processors that are operatively connected. The memory 14 can include one or more non-transitory computer-readable storage media, such as RAM, ROM, EEPROM, EPROM, flash memory devices, magnetic disks, etc., and combinations thereof. The memory 14 can store data 16 and instructions 18 which are executed by the processor 12 to cause the user computing device 2 to perform operations as described herein.

In some implementations, the user computing device 2 can store or include one or more machine-learned models 20. For example, the machine-learned models 20 can be or can otherwise include various machine-learned models such as neural networks (e.g., deep neural networks) or other types of machine-learned models, including non-linear models or linear models. Neural networks can include feed-forward neural networks, recurrent neural networks (e.g., long short-term memory recurrent neural networks), convolutional neural networks or other forms of neural networks. Some example machine-learned models can leverage an attention mechanism such as self-attention. For example, some example machine-learned models can include multi-headed self-attention models (e.g., transformer models).

In some implementations, one or more machine-learned models 20 can be received from the server computing system 30 over network 70, stored in the computing device memory 14, and used or otherwise implemented by the one or more processors 12. In some implementations, the computing device 2 can implement multiple parallel instances of a machine-learned model 20. In some embodiments, machine-learned model(s) 20 can perform personalization of one or more content items, or rendering thereof for or on the client device 102, 2.

Additionally, or alternatively, one or more machine-learned models 40 can be included in or otherwise stored and implemented by the server computing system 30 that communicates with the computing device 2 according to a client-server relationship. For example, the machine-learned models 40 can be implemented by the server computing system 40 as a portion of a web service. For instance, the server computing system 30 can communicate with the computing device 2 over a local intranet or internet connection. For instance, the computing device 2 can be a workstation or endpoint in communication with the server computing system 30, with implementation of the model 40 on the server computing system 30 being remotely performed and an output provided (e.g., cast, streamed, etc.) to the computing device 2. Thus, one or more models 20 can be stored and implemented at the user computing device 2 or one or more models 40 can be stored and implemented at the server computing system 30.

The computing device 2 can also include one or more input components that receive user input. For example, a user input component can be a touch-sensitive component (e.g., a touch-sensitive display screen or a touch pad) that is sensitive to the touch of a user input object (e.g., a finger or a stylus). The touch-sensitive component can serve to implement a virtual keyboard. Other example user input components include a microphone, a traditional keyboard, or other means by which a user can provide user input.

The server computing system 30 can include one or more processors 32 and a memory 34. The one or more processors 32 can be any suitable processing device (e.g., a processor core, a microprocessor, an ASIC, an FPGA, a controller, a microcontroller, etc.) and can be one processor or a plurality of processors that are operatively connected. The memory 34 can include one or more non-transitory computer-readable storage media, such as RAM, ROM, EEPROM, EPROM, flash memory devices, magnetic disks, etc., and combinations thereof. The memory 34 can store data 36 and instructions 38 which are executed by the processor 32 to cause the server computing system 30 to perform operations as described herein.

In some implementations, the server computing system 30 includes or is otherwise implemented by one or more server computing devices. In instances in which the server computing system 130 includes plural server computing devices, such server computing devices can operate according to sequential computing architectures, parallel computing architectures, or some combination thereof.

As described above, the server computing system 30 can store or otherwise include one or more machine-learned models 40. For example, the models 40) can be or can otherwise include various machine-learned models. Example machine-learned models include neural networks or other multi-layer non-linear models. Example neural networks include feed forward neural networks, deep neural networks, recurrent neural networks, and convolutional neural networks. Some example machine-learned models can leverage an attention mechanism such as self-attention. For example, some example machine-learned models can include multi-headed self-attention models (e.g., transformer models).

In some embodiments, model(s) 40) includes mixed effects models. For instance, model(s) 40) can include one or more linear mixed effects models, generalized linear mixed effects models, etc.

The computing device 2 or the server computing system 30 can train example embodiments of a machine-learned model (e.g., including models 20 or 40). In some embodiments, the computing device 2 or the server computing system 30 can train example embodiments of a machine-learned model (e.g., including models 20 or 40) via interaction with the training computing system 50. In some embodiments, the training computing system 50 can be communicatively coupled over the network 70. The training computing system 50 can be separate from the server computing system 30 or can be a portion of the server computing system 30.

The training computing system 50 can include one or more processors 52 and a memory 54. The one or more processors 52 can be any suitable processing device (e.g., a processor core, a microprocessor, an ASIC, an FPGA, a controller, a microcontroller, etc.) and can be one processor or a plurality of processors that are operatively connected. The memory 54 can include one or more non-transitory computer-readable storage media, such as RAM, ROM, EEPROM, EPROM, flash memory devices, magnetic disks, etc., and combinations thereof. The memory 54 can store data 56 and instructions 58 which are executed by the processor 52 to cause the training computing system 50 to perform operations. In some implementations, the training computing system 50 includes or is otherwise implemented by one or more server computing devices.

Parameters of the model(s) can be trained, in some embodiments, using various training or learning techniques, such as, for example, backwards propagation of errors. For example, an objective or loss can be backpropagated through pretraining, general training, or finetuning pipeline(s) to update one or more parameters of the model(s) (e.g., based on a gradient of the loss function). Various determinations of loss can be used, such as mean squared error, likelihood loss, cross entropy loss, hinge loss, or various other loss functions. Gradient descent techniques can be used to iteratively update the parameters over a number of training iterations. In some implementations, performing backwards propagation of errors can include performing truncated backpropagation through time. The pipeline(s) can perform a number of generalization techniques (e.g., weight decays, dropouts, etc.) to improve the generalization capability of the models being trained.

The model trainer 60 can include computer logic utilized to provide desired functionality. The model trainer 60 can be implemented in hardware, firmware, or software controlling a general-purpose processor. For example, in some implementations, the model trainer 60 includes program files stored on a storage device, loaded into a memory, and executed by one or more processors. In other implementations, the model trainer 60 includes one or more sets of computer-executable instructions that are stored in a tangible computer-readable storage medium such as RAM, hard disk, or optical or magnetic media.

In some embodiments, the model trainer 60 can implement the techniques of the present disclosure to learn one or more parameters of mixed effects models. For instance, the model trainer 60) can implement the techniques of the present disclosure to learn one or more parameters of one or more linear mixed effects models, generalized linear mixed effects models, etc.

The network 70 can be any type of communications network, such as a local area network (e.g., intranet), wide area network (e.g., Internet), or some combination thereof and can include any number of wired or wireless links. In general, communication over the network 70 can be carried via any type of wired or wireless connection, using a wide variety of communication protocols (e.g., TCP/IP, HTTP, SMTP, FTP), encodings or formats (e.g., HTML, XML), or protection schemes (e.g., VPN, secure HTTP, SSL).

FIG. 3A illustrates one example computing system that can be used to implement the present disclosure. Other computing systems can be used as well. For example, in some implementations, the computing device 2 can include the model trainer 60. In such implementations, a training pipeline can be used locally at the computing device 2. In some of such implementations, the computing device 2 can implement the model trainer 60 to personalize the model(s) based on device-specific data.

FIG. 3B depicts a block diagram of an example computing device 80 that performs according to example embodiments of the present disclosure. The computing device 80 can be a user computing device or a server computing device. The computing device 80 can include a number of applications (e.g., applications 1 through N). Each application can contain its own machine learning library and machine-learned model(s). For example, each application can include a machine-learned model. Example applications include a text messaging application, an email application, a dictation application, a virtual keyboard application, a browser application, etc. As illustrated in FIG. 2B, each application can communicate with a number of other components of the computing device, such as, for example, one or more sensors, a context manager, a device state component, or additional components. In some implementations, each application can communicate with each device component using an API (e.g., a public API). In some implementations, the API used by each application is specific to that application.

FIG. 3C depicts a block diagram of an example computing device 80 that performs according to example embodiments of the present disclosure. The computing device 80) can be a user computing device or a server computing device. The computing device 80 can include a number of applications (e.g., applications 1 through N). Each application is in communication with a central intelligence layer. Example applications include a text messaging application, an email application, a dictation application, a virtual keyboard application, a browser application, etc. In some implementations, each application can communicate with the central intelligence layer (and model(s) stored therein) using an API (e.g., a common API across all applications).

The central intelligence layer can include a number of machine-learned models. For example, as illustrated in FIG. 3C, a respective machine-learned model can be provided for each application and managed by the central intelligence layer. In other implementations, two or more applications can share a single machine-learned model. For example, in some implementations, the central intelligence layer can provide a single model for all of the applications. In some implementations, the central intelligence layer is included within or otherwise implemented by an operating system of the computing device 80.

The central intelligence layer can communicate with a central device data layer. The central device data layer can be a centralized repository of data for the computing device 80. As illustrated in FIG. 3C, the central device data layer can communicate with a number of other components of the computing device, such as, for example, one or more sensors, a context manager, a device state component, or additional components. In some implementations, the central device data layer can communicate with each device component using an API (e.g., a private API).

### Example Methods

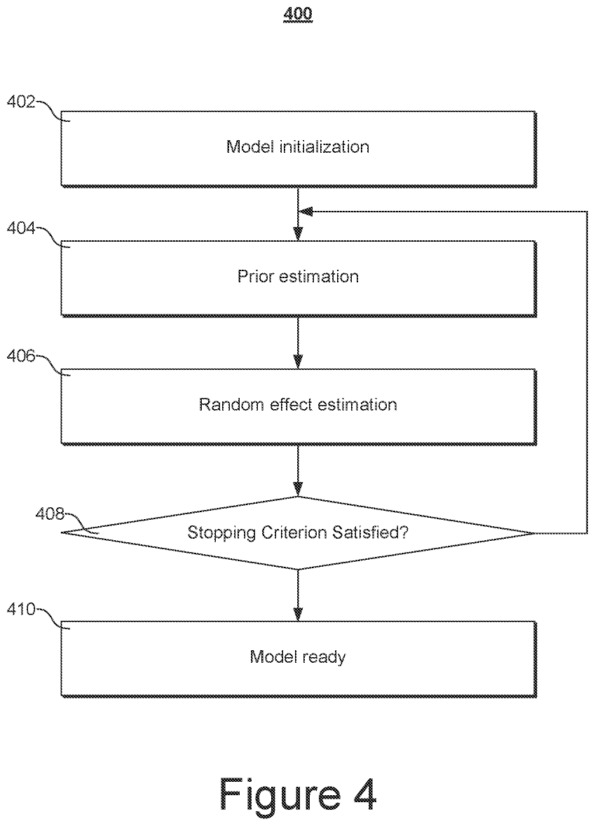

As described above, various models (e.g., linear mixed effects models, generalized linear mixed effects models, etc.) can be optimized in an iterative fashion. For example, FIG. 4 depicts a flow chart diagram of an example method 400 to perform according to example embodiments of the present disclosure. Although FIG. 4 depicts steps performed in a particular order for purposes of illustration and discussion, the methods of the present disclosure are not limited to the particularly illustrated order or arrangement. The various steps of the example method 400 can be omitted, rearranged, combined, or adapted in various ways without deviating from the scope of the present disclosure.

At 402, the example method 400 includes a model initiation stage. The mixed effects model can be initialized by, for example, populating model parameters with initial values. The mixed effects model can be initialized by, for example, obtaining an optimization starting point in the vicinity of a local optimum. The mixed effects model can be initialized by, for example, obtaining an optimization starting point in a locally convex surface of the response. A linear mixed effects model can be initialized by, for example, solving a linear regression model (e.g., a linear mixed effects model with infinite prior values). A generalized linear mixed effects model can be initialized by, for example, solving a generalized linear mixed model with a given initial prior value.

At 404, the example method 400 includes a prior estimation stage.

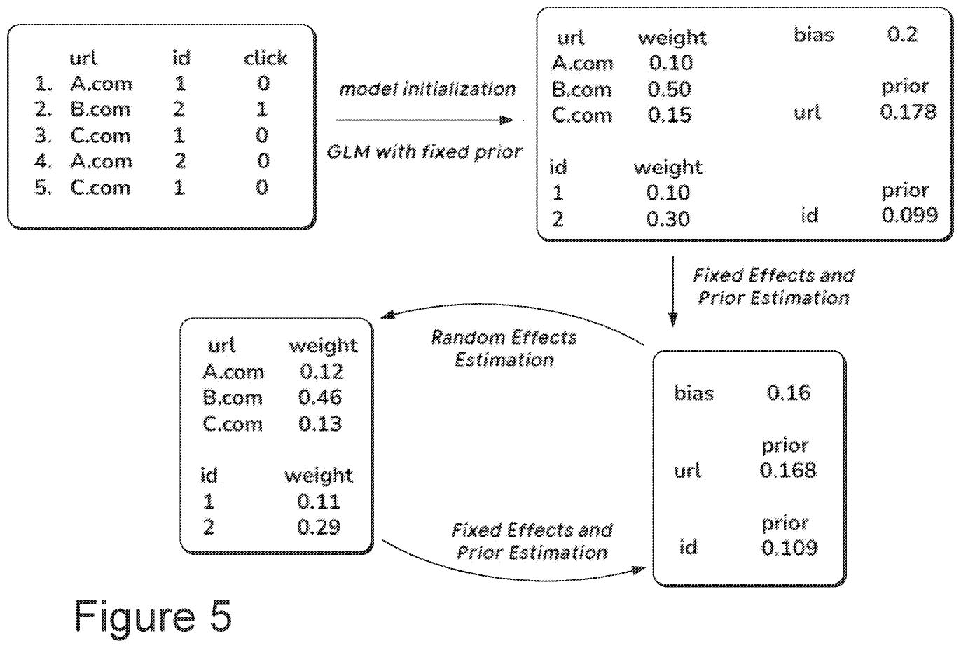

For example FIG. 5 demonstrates a simplistic example of a Poisson-Lognormal model

Pois(0,(0.1+0.1+0.2))·N(0.1;0,0.178)·N(0.1;0,0.099)

initialized by solving a generalized linear model with a fixed prior.

With reference again to FIG. 4, at 404, the example method 400 includes a prior estimation stage. For example, in a prior estimation stage, values associated with fixed effects and priors can be estimated based on the initalized random effects parameters. For instance, with reference to the terminology used herein, method 400 at 404 can include estimating \tilde{β} and \tilde{σ} (see, e.g., Algorithms 1 and 2). For instance, as shown in FIG. 5, in the prior estimation stage, the bias(es) and prior(s) can be estimated.

With reference again to FIG. 4, at 406, the example method 400 includes a random effect estimation stage. For example, in the random effects/weight estimation stage, values associated with the levels of random effects can be estimated. For instance, with reference to the terminology used herein, method 400 at 406 can include estimating \tilde{γ} based on the obtained \tilde{β} and \tilde{σ}. For instance, as shown in FIG. 5, the Fixed Effects and Prior Estimation can be used in a first iteration to perform Random Effects Estimation.

With reference again to FIG. 4, at 408, the example method 400 evaluates whether a stopping criterion is satisfied. For example, a stopping criterion can correspond to a stability criterion for the estimated values, a convergence criterion, an accuracy or other evaluation criterion over the modeled data (e.g., session data 100).

In some embodiments, if the stopping criterion is not satisfied, one or more iterations can be performed. For instance, the example method 400 can include a return from 408 to again perform at 404 the prior estimation. For instance, as shown in FIG. 5, the results of the Random Effects Estimation can be used to (again) perform Fixed Effects and Prior Estimation. These iterations can be performed until a stopping criterion is satisfied at 408.

With reference again to FIG. 4, at 410, the example method 400 can output one or more model parameters such that the model can be implemented. For instance, with reference to the terminology used herein, the output model parameters can include \tilde{γ}, \tilde{β}, \tilde{σ}, etc.

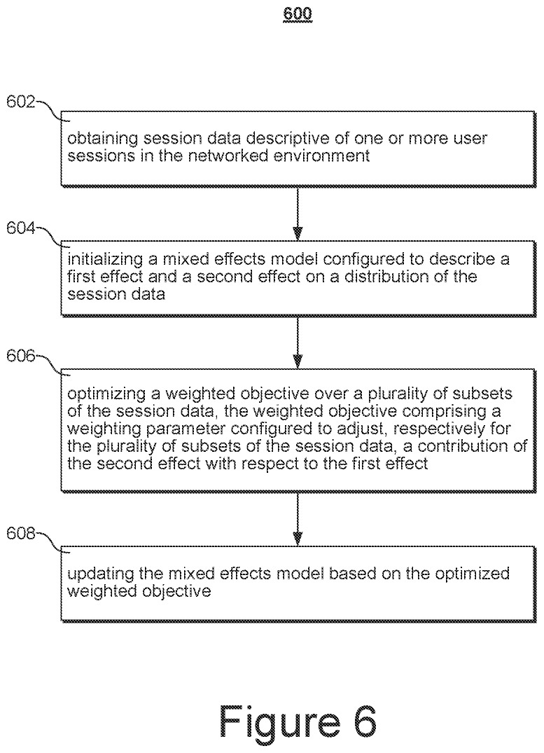

FIG. 6 depicts a flow chart diagram of an example method 600 to perform according to example embodiments of the present disclosure. Although FIG. 6 depicts steps performed in a particular order for purposes of illustration and discussion, the methods of the present disclosure are not limited to the particularly illustrated order or arrangement. The various steps of the example method 600 can be omitted, rearranged, combined, or adapted in various ways without deviating from the scope of the present disclosure.

At 602, the example method 600 includes obtaining session data descriptive of one or more user sessions in a networked environment. For instance, session data can include data descriptive of one or more features or characteristics of a user session on a client device. For instance, a client device can be executing an application or accessing streamed content via a web portal. Session data can describe various features or characteristics of the client device, application, content, context, etc.

At 604, the example method 600 includes initializing a mixed effects model. For instance, initializing the model can include estimating an initial set of parameters that characterize the model. For instance, with reference to the terminology used herein, the model parameters to be initialized can include \tilde{γ}, \tilde{β}, \tilde{σ}, etc. The model parameters can be initialized by, for example, estimating value(s) for the parameters. In some embodiments, value(s) can be estimated for the parameters by simplifying the model and solving/fitting the simplified model to the session data.

At 604, the mixed effects model can be configured to describe a first effect and a second effect on a distribution of the session data. For instance, a first effect can be an effect of interest relating to a parameter or feature being studied. A second effect can be another effect that may not be of immediate interest to a given exercise or modeling implementation. For instance, the second effect can include one or more background effects that can be modeled according to one or more probability distributions (e.g., a random effect sampled from one or more probability distributions).

In some embodiments, the first effect is associated with a causal relationship between an intermediate interaction with a content item rendered on a respective client device, the content item transmitted to the client device according to one or more distribution parameters, and a target interaction with a target networked resource associated with the content item.

At 606, the example method 600 includes optimizing a weighted objective over a plurality of subsets of the session data, the weighted objective comprising a weighting parameter configured to adjust, respectively for the plurality of subsets of the session data, a contribution of the second effect with respect to the first effect. For instance, example weighted objectives are provided herein in, e.g., Equations 33, 34, 35, 36, 37, 38, 41, etc.

In some embodiments, the weight for the weighted objective can be based on one or more characteristics of a subset of the session data. In some embodiments, the second effect is associated with one or more levels of values in the session data, and the weighted parameter is based on a frequency that a respective level associated with an input to the weighted objective appears in the session data.

In some embodiments, the weighted parameter is based on a size of a respective subset of the plurality of subsets.

In some embodiments, optimizing the weighted objective comprises inverting, by the computing system, a data structure descriptive of at least a portion of a respective subset of the plurality of subsets.

In some embodiments, the weighted objective is optimized by stochastic gradient descent.

In some embodiments, the weighted objective is optimized over the plurality of subsets at least partially in parallel.

At 608, the example method 600 includes updating the mixed effects model based on the optimized weighted objective. For instance, the output of the optimization can include one or more sets of model parameters. For instance, with reference to the terminology used herein, the output model parameters can include \tilde{γ}, \tilde{β}, \tilde{σ}, etc. In some embodiments, for instance, an output of the optimization of the weighted objective can include one or more values for \tilde{γ}, which can in turn be used to determine one or more values for \tilde{β}, \tilde{σ}, etc.

In some embodiments, the mixed effects model can be updated iteratively.

In some embodiments, the mixed effects model disambiguates the first effect and the second effect. For instance, in some embodiments the mixed effects model can describe an influence or one or more parameters of interest on an outcome (e.g., a system performance, a system utilization, resource usage, etc.) that is disambiguated from the background influence(s) of other parameters.

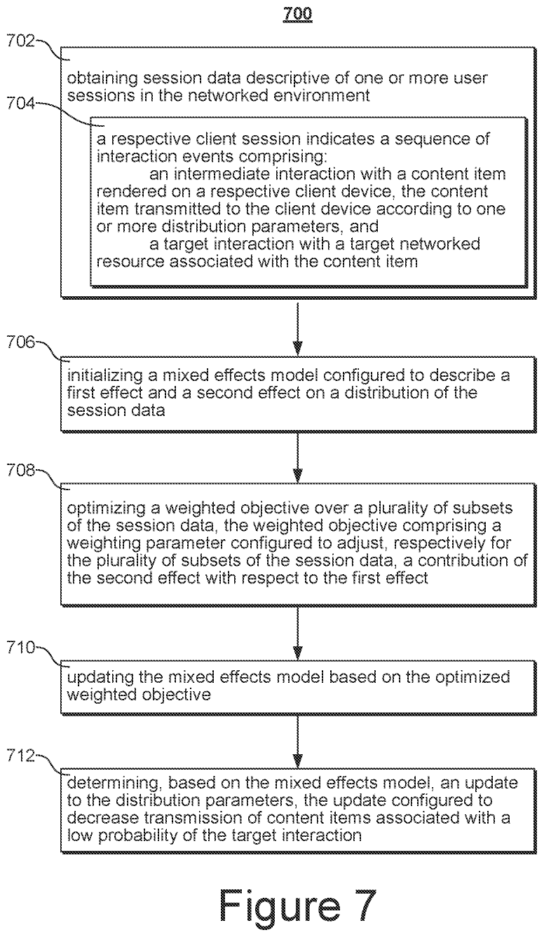

FIG. 7 depicts a flow chart diagram of an example method 700 to perform according to example embodiments of the present disclosure. Although FIG. 7 depicts steps performed in a particular order for purposes of illustration and discussion, the methods of the present disclosure are not limited to the particularly illustrated order or arrangement. The various steps of the example method 700 can be omitted, rearranged, combined, or adapted in various ways without deviating from the scope of the present disclosure.

At 702, the example method 700 includes obtaining session data descriptive of one or more user sessions in the networked environment. For instance, session data can include data descriptive of one or more features or characteristics of a user session on a client device. For instance, a client device can be executing an application or accessing streamed content via a web portal. Session data can describe various features or characteristics of the client device, application, content, context, etc.

In some embodiments, a respective client session (e.g., at 704) indicates a sequence of interaction events. In some embodiments, one interaction event can include an intermediate interaction with a content item rendered on a respective client device. For instance, the content item can be transmitted to the client device according to one or more distribution parameters. In some embodiments, another interaction event can include a target interaction with a target networked resource associated with the content item. For instance, a target networked resource can be linked to other otherwise accessed by interaction with the content item.

At 706, the example method 700 includes initializing a mixed effects model. For instance, initializing the model can include estimating an initial set of parameters that characterize the model. For instance, with reference to the terminology used herein, the model parameters to be initialized can include \tilde{γ}, \tilde{β}, \tilde{σ}, etc. The model parameters can be initialized by, for example, estimating value(s) for the parameters. In some embodiments, value(s) can be estimated for the parameters by simplifying the model and solving/fitting the simplified model to the session data.

At 706, the mixed effects model can be configured to describe a first effect and a second effect on a distribution of the session data. For instance, a first effect can be an effect of interest relating to a parameter or feature being studied. A second effect can be another effect that may not be of immediate interest to a given exercise or modeling implementation. For instance, the second effect can include one or more background effects that can be modeled according to one or more probability distributions (e.g., a random effect sampled from one or more probability distributions).

In some embodiments, the first effect is associated with a causal relationship between an intermediate interaction with a content item rendered on a respective client device, the content item transmitted to the client device according to one or more distribution parameters, and a target interaction with a target networked resource associated with the content item.

At 708, the example method 700 includes optimizing a weighted objective over a plurality of subsets of the session data, the weighted objective comprising a weighting parameter configured to adjust, respectively for the plurality of subsets of the session data, a contribution of the second effect with respect to the first effect. For instance, example weighted objectives are provided herein in, e.g., Equations 33, 34, 35, 36, 37, 38, 41, etc.

In some embodiments, the weight for the weighted objective can be based on one or more characteristics of a subset of the session data. In some embodiments, the second effect is associated with one or more levels of values in the session data, and the weighted parameter is based on a frequency that a respective level associated with an input to the weighted objective appears in the session data.

In some embodiments, the weighted parameter is based on a size of a respective subset of the plurality of subsets.

In some embodiments, optimizing the weighted objective comprises inverting, by the computing system, a data structure descriptive of at least a portion of a respective subset of the plurality of subsets.

In some embodiments, the weighted objective is optimized by stochastic gradient descent.

In some embodiments, the weighted objective is optimized over the plurality of subsets at least partially in parallel.

At 710, the example method 700 includes updating the mixed effects model based on the optimized weighted objective. For instance, the output of the optimization can include one or more sets of model parameters. For instance, with reference to the terminology used herein, the output model parameters can include \tilde{γ}, \tilde{β}, \tilde{σ}, etc. In some embodiments, for instance, an output of the optimization of the weighted objective can include one or more values for \tilde{γ}, which can in turn be used to determine one or more values for \tilde{β}, \tilde{σ}, etc.

In some embodiments, the mixed effects model can be updated iteratively.

In some embodiments, the mixed effects model disambiguates the first effect and the second effect. For instance, in some embodiments the mixed effects model can describe an influence or one or more parameters of interest on an outcome (e.g., a system performance, a system utilization, resource usage, etc.) that is disambiguated from the background influence(s) of other parameters.

At 712, the example method 700 can include determining, based on the mixed effects model, an update to the distribution parameters, the update configured to decrease transmission of content items associated with a low probability of the target interaction. In some embodiments, the low probability of the target interaction can be determined by reference to a threshold probability (e.g., below the threshold).

For instance, as illustrated in FIG. 2, a modeling system 210 can provide output(s) 150 that can be used to control or influence the modeled system 220. For example, the modeled system 220 can include a networked environment for distribution of content items that provide access to target networked resources. It may be desired to improve a utilization rate of the distributed content items to decrease the transmission of content items over the network that are not used or otherwise prioritize bandwidth and processing resources for distributing content items that are used, thereby improving the access of the target resources by client devices by the distributed content items.

The utilization of the content items (e.g., engagement or interaction therewith, such as by a selection, click, etc.) can be an effect of interest associated with one or more parameters of interest. The mixed effects model(s) 130 of the present disclosure can be used to model the effects of the one or more parameters of interest. The mixed effects model(s) 130 can also account for other parameters that may not be of interest. In some embodiments, the mixed effects model(s) 130 can be implemented in accordance with, for example, example method 700 to update one or more distribution parameters to improve the utilization of the content items. The update can, in some embodiments, be based on an optimization of the weighted objective(s) as described herein.

### Additional Disclosure

The technology discussed herein makes reference to servers, databases, software applications, and other computer-based systems, as well as actions taken and information sent to and from such systems. The inherent flexibility of computer-based systems allows for a great variety of possible configurations, combinations, and divisions of tasks and functionality between and among components. For instance, processes discussed herein can be implemented using a single device or component or multiple devices or components working in combination. Databases and applications can be implemented on a single system or distributed across multiple systems. Distributed components can operate sequentially or in parallel.

While the present subject matter has been described in detail with respect to various specific example embodiments thereof, each example is provided by way of explanation, not limitation of the disclosure. Those skilled in the art, upon attaining an understanding of the foregoing, can readily produce alterations to, variations of, and equivalents to such embodiments. Accordingly, the subject disclosure does not preclude inclusion of such modifications, variations or additions to the present subject matter as would be readily apparent to one of ordinary skill in the art. For instance, features illustrated or described as part of one embodiment can be used with another embodiment to yield a still further embodiment. Thus, it is intended that the present disclosure cover such alterations, variations, and equivalents.

Aspects of the disclosure have been described in terms of illustrative embodiments thereof. Any and all features in the following claims can be combined or rearranged in any way possible, including combinations of claims not explicitly enumerated in combination together, as the example claim dependencies listed herein should not be read as limiting the scope of possible combinations of features disclosed herein. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Clauses and other sequences of items joined by a particular conjunction such as “or,” for example, can refer to “and/or,” “at least one of”, “any combination of” example elements listed therein, etc. Also, terms such as “based on” should be understood as “based at least in part on.”

1. (canceled)

2. A computer-implemented method for modeling mixed effects in a networked environment, the method comprising:
obtaining, by a computing system comprising one or more processors, session data descriptive of one or more user sessions in the networked environment;
initializing, by the computing system, a mixed effects model configured to describe a first effect and a second effect on a distribution of the session data;
optimizing, by the computing system, a weighted objective over a plurality of subsets of the session data, the weighted objective comprising a weighting parameter configured to adjust, respectively for the plurality of subsets of the session data, a contribution of the second effect with respect to the first effect; and
updating, by the computing system, the mixed effects model based on the optimized weighted objective.

3. The method of claim 2, wherein the second effect is associated with one or more levels of values in the session data, and wherein the weighted parameter is based on a frequency that a respective level associated with an input to the weighted objective appears in the session data.

4. The method of claim 2, wherein the weighted parameter is based on a size of a respective subset of the plurality of subsets.

5. The method of claim 2, wherein optimizing the weighted objective comprises inverting, by the computing system, a data structure descriptive of at least a portion of a respective subset of the plurality of subsets.

6. The method of claim 2, wherein the mixed effects model disambiguates the first effect and the second effect.

7. The method of claim 2, wherein the first effect is associated with a causal relationship between
an intermediate interaction with a content item rendered on a respective client device, the content item transmitted to the client device according to one or more distribution parameters, and
a target interaction with a target networked resource associated with the content item.

8. The method of claim 2, wherein the weighted objective is optimized by stochastic gradient descent.

9. The method of claim 2, comprising:
estimating, by the computing system, a prior for a feature corresponding to the second effect; and
estimating, by the computing system and based on the estimated prior, one or more weights for modeling the feature in the mixed effects model.

10. The method of claim 2, wherein the weighted objective is optimized over the plurality of subsets at least partially in parallel.

11. The method of claim 2, wherein the mixed effects model is updated by a first entity service provider system, wherein the first entity service provider system provides a modeling service to model behavior of a second entity content distribution system.

12. The method of claim 2, wherein a first entity service provider system implements the updated mixed effects model to control a distribution of content items on a second entity content distribution system.

13. (canceled)

14. (canceled)

15. A computing system, comprising:
one or more processors; and
one or more non-transitory computer-readable media storing instructions that are executable to cause the computing system to perform operations, the operations comprising:
obtaining session data descriptive of one or more user sessions in a networked environment;
initializing a mixed effects model configured to describe a first effect and a second effect on a distribution of the session data;
optimizing a weighted objective over a plurality of subsets of the session data, the weighted objective comprising a weighting parameter configured to adjust, respectively for the plurality of subsets of the session data, a contribution of the second effect with respect to the first effect; and
updating the mixed effects model based on the optimized weighted objective.

16. The computing system of claim 15, wherein the second effect is associated with one or more levels of values in the session data, and wherein the weighted parameter is based on a frequency that a respective level associated with an input to the weighted objective appears in the session data.

17. The computing system of claim 15, wherein the weighted parameter is based on a size of a respective subset of the plurality of subsets.

18. The computing system of claim 15, wherein optimizing the weighted objective comprises inverting, by the computing system, a data structure descriptive of at least a portion of a respective subset of the plurality of subsets.

19. The computing system of claim 15, wherein the mixed effects model disambiguates the first effect and the second effect.

20. The computing system of claim 15, wherein the first effect is associated with a causal relationship between
an intermediate interaction with a content item rendered on a respective client device, the content item transmitted to the client device according to one or more distribution parameters, and
a target interaction with a target networked resource associated with the content item.

21. The computing system of claim 15, wherein the weighted objective is optimized by stochastic gradient descent.

22. One or more non-transitory computer-readable media storing instructions that are executable to cause a computing system to perform operations, the operations comprising:
obtaining session data descriptive of one or more user sessions in a networked environment;
initializing a mixed effects model configured to describe a first effect and a second effect on a distribution of the session data;
optimizing a weighted objective over a plurality of subsets of the session data, the weighted objective comprising a weighting parameter configured to adjust, respectively for the plurality of subsets of the session data, a contribution of the second effect with respect to the first effect; and
updating the mixed effects model based on the optimized weighted objective.

23. The one or more non-transitory computer-readable media of claim 22, wherein the weighted objective is optimized by stochastic gradient descent.
